(19) United States
(12) Patent Application Publication
(10) Pub. No.: US 2025/0301892 A1
(43) Pub. Date: Sep. 25, 2025

(54) OPTICAL DEVICE AND OPTICAL METHOD

(71) Applicant: HTC Corporation, Taoyuan City (TW)

(72) Inventors: Chun-Yih WU, Taoyuan City (TW); Ta-Chun PU, Taoyuan City (TW); Yen-Liang KUO, Taoyuan City (TW)

(73) Assignee: HTC Corporation, Taoyuan City (TW)

(21) Appl. No.: 19/060,045

(22) Filed: Feb. 21, 2025

Related U.S. Application Data
(60) Provisional application No. 63/569,287, filed on Mar. 25, 2024.

(30) Foreign Application Priority Data
Feb. 4, 2025 (TW) 114103927

(51) Int. Cl. H10K 59/80; G02B 27/00; G02B 27/01; H10K 39/34

(52) U.S. Cl. CPC H10K 59/879; G02B 27/0093; G02B 27/0172; H10K 39/34

(57) ABSTRACT

An optical device includes a first metamaterial lens element, a second metamaterial lens element, an OLED (Organic Light-Emitting Diode) layer, an IR (Infrared) sensor layer, a circuit layer, and a substrate. The OLED layer is adjacent to the first metamaterial lens element. The IR sensor layer is adjacent to the second metamaterial lens element. The circuit layer is configured to carry the OLED layer and the IR sensor layer. The substrate is configured to carry the circuit layer. The OLED layer is configured to generate a visible light. The visible light is transmitted outwardly through the first metamaterial lens element. The IR sensor layer is configured to receive an IR light through the second metamaterial lens element.

### CROSS REFERENCE TO RELATED APPLICATIONS

This application claims the benefit of U.S. Provisional Application No. 63/569,287, filed on Mar. 25, 2024, and also claims priority of Taiwan Patent Application No. 114103927, filed on Feb. 4, 2025, the entirety of which are incorporated by reference herein.

### BACKGROUND OF THE INVENTION

### Field of the Invention

The invention relates in general to an optical device, and more particularly, it relates to an optical device and an optical method.

### Description of the Related Art

In the optical field, there must often be a trade-off between refractive index and dispersion when dealing with conventional optical materials. However, optical materials with a low refractive index tend to limit the performance of the optical device in which they are used. They may also tend to increase the overall device size. Accordingly, there is a need to propose a novel solution for solving this problem of the prior art.

### BRIEF SUMMARY OF THE INVENTION

In an exemplary embodiment, the invention is directed to an optical device that includes a first metamaterial lens element, a second metamaterial lens element, an OLED (Organic Light-Emitting Diode) layer, an IR (Infrared) sensor layer, a circuit layer, and a substrate. The OLED layer is disposed adjacent to the first metamaterial lens element. The IR sensor layer is disposed adjacent to the second metamaterial lens element. The circuit layer is configured to carry the OLED layer and the IR sensor layer. The substrate is configured to carry the circuit layer. The OLED layer generates a visible light. The visible light is transmitted outwardly through the first metamaterial lens element. The IR sensor layer receives an IR light through the second metamaterial lens element.

In some embodiments, the first metamaterial lens element and the second metamaterial lens element have different periodical structures.

In some embodiments, the first metamaterial lens element provides a first refractive index for the visible light.

In some embodiments, the first refractive index is greater than 1.

In some embodiments, the second metamaterial lens element provides a second refractive index for the IR light.

In some embodiments, the second refractive index is smaller than 1.

In some embodiments, the optical device is an HMD (Head Mounted Display).

In some embodiments, the optical device further includes an IR light source for transmitting an incident light to an eyeball. The IR light is equivalent to a reflection light from the eyeball.

In some embodiments, if the incident light has an LHCP (Left-Handed Circular Polarization), the reflection light will have an RHCP (Right-Handed Circular Polarization).

In some embodiments, if the incident light has an RHCP, the reflection light will have an LHCP.

In some embodiments, the optical device supports an eye-tracking function.

In some embodiments, the second metamaterial lens element only receives either the IR light with an LHCP or the IR light with an RHCP.

In another exemplary embodiment, the invention is directed an optical method that includes the steps of: providing a first metamaterial lens element, a second metamaterial lens element, an OLED layer, and an IR sensor layer, wherein the OLED layer is adjacent to the first metamaterial lens element, and the IR sensor layer is adjacent to the second metamaterial lens element; generating a visible light by the OLED layer, wherein the visible light is transmitted outwardly through the first metamaterial lens element; and receiving an IR light through the second metamaterial lens element by the IR sensor layer.

In some embodiments, the optical method further includes the step of providing a first refractive index for the visible light by the first metamaterial lens element.

In some embodiments, the optical method further includes the step of providing a second refractive index for the IR light by the second metamaterial lens element.

In some embodiments, the optical method further includes the step of transmitting an incident light to an eyeball by an IR light source. The IR light is equivalent to a reflection light from the eyeball.

In some embodiments, the optical method further includes the step of receiving either the IR light with an LHCP or the IR light with an RHCP by the second metamaterial lens element.

### BRIEF DESCRIPTION OF DRAWINGS

The invention can be more fully understood by reading the subsequent detailed description and examples with references made to the accompanying drawings, wherein:

FIG. 1 is a sectional view of an optical device according to an embodiment of the invention;

FIG. 2 is a sectional view of an optical device according to an embodiment of the invention; and

FIG. 3 is a flowchart of an optical method according to an embodiment of the invention.

### DETAILED DESCRIPTION OF THE INVENTION

In order to illustrate the foregoing and other purposes, features and advantages of the invention, the embodiments and figures of the invention will be described in detail as follows.

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. The term “substantially” means the value is within an acceptable error range. One skilled in the art can solve the technical problem within a predetermined error range and achieve the proposed technical performance. Also, the term “couple” is intended to mean either an indirect or direct electrical connection. Accordingly, if one device is coupled to another device, that connection may be through a direct electrical connection, or through an indirect electrical connection via other devices and connections.

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

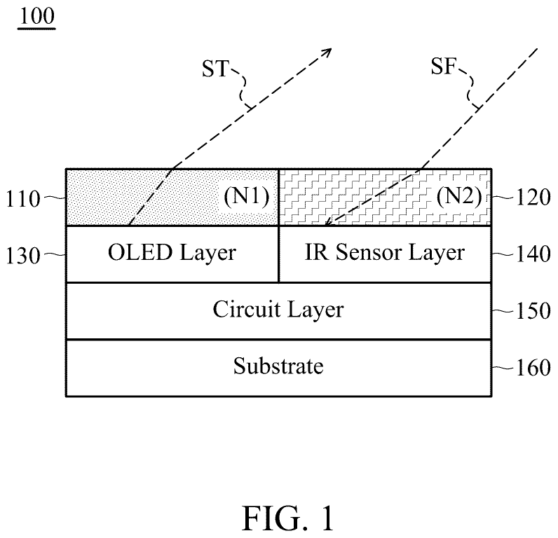

FIG. 1 is a sectional view of an optical device 100 according to an embodiment of the invention. The optical device 100 may be applied in a mobile device, such as a smart phone, a tablet computer, or a notebook computer. As shown in FIG. 1, the optical device 100 includes a first metamaterial lens element 110, a second metamaterial lens element 120, an OLED (Organic Light-Emitting Diode) layer 130, an IR (Infrared) sensor layer 140, a circuit layer 150, and a substrate 160. It should be understood that the optical device 100 may further include other components, such as a processor, a battery element, and/or a housing, although they are not displayed in FIG. 1.

The shapes and types of the first metamaterial lens element 110 and the second metamaterial lens element 120 are not limited in the invention. The first metamaterial lens element 110 has a first periodical structure. The second metamaterial lens element 120 has a second periodical structure. For example, the first periodical structure of the first metamaterial lens element 110 may include a plurality of first dielectric units and a plurality of second dielectric units (not shown), and the first dielectric units may be interleaved with the second dielectric units. Furthermore, the second periodical structure of the second metamaterial lens element 120 may include a plurality of third dielectric units and a plurality of fourth dielectric units (not shown), and the third dielectric units may be interleaved with the fourth dielectric units.

A spatial superstrate of the optical device 100 can be formed by the first metamaterial lens element 110 and the second metamaterial lens element 120. It should be noted that the first periodical structure of the first metamaterial lens element 110 is different from the second periodical structure of the second metamaterial lens element 120. In some embodiments, the thickness of the first periodical structure of the first metamaterial lens element 110 is from 50 nm to 150 nm, and the distance between any adjacent first dielectric units is from 100 nm to 350 nm. In some embodiments, the thickness of the second periodical structure of the second metamaterial lens element 120 is from 100 nm to 400 nm, and the distance between any adjacent third dielectric units is from 500 nm to 1000 nm. For example, the second periodical structure of the second metamaterial lens element 120 may be considered as a circularly polarized resonator structure, and the IR light in a specific circular polarization mode may pass through it. In addition, the circularly polarized resonator structure may be classified as an asymmetric structure, which may be different from the first periodical structure of the first metamaterial lens element 110.

For example, the OLED layer 130 may include a plurality of OLED units (not shown). The OLED layer 130 is disposed adjacent to the first metamaterial lens element 110. In some embodiments, the first metamaterial lens element 110 is disposed on the OLED layer 130, and is configured to cover the OLED layer 130. In alternative embodiments, the OLED layer 130 is directly attached to the first metamaterial lens element 110. It should be noted that the term “adjacent” or “close” over the disclosure means that the distance (spacing) between two corresponding elements is smaller than a predetermined distance (e.g., 10 mm or the shorter), or means that the two corresponding elements directly touch each other (i.e., the aforementioned distance/spacing between them is reduced to 0).

For example, the IR sensor layer 140 may include a plurality of OPD (Organic Photodiode) units (not shown). The IR sensor layer 140 is disposed adjacent to the second metamaterial lens element 120. In some embodiments, the second metamaterial lens element 120 is disposed on the IR sensor layer 140, and is configured to cover the IR sensor layer 140. In alternative embodiments, the IR sensor layer 140 is directly attached to the second metamaterial lens element 120.

The circuit layer 150 may include a variety of circuits, which are not limited in the invention. The circuit layer 150 is configured to carry the OLED layer 130 and the IR sensor layer 140. The substrate 160 is configured to carry the circuit layer 150. In some embodiments, the circuit layer 150 includes a first controller and a second controller (not shown). The first controller is configured to drive the OLED layer 130. The second controller is configured to control the IR light detection process of the IR sensor layer 140.

Generally, the operational principles of the optical device 100 can be described as follows. The OLED layer 130 can generate a visible light ST. The visible light ST can be transmitted outwardly through the first metamaterial lens element 110. The first metamaterial lens element 110 can provide a first refractive index N1 for the visible light ST, so as to fine-tune the direction and phase of the visible light ST. The IR sensor layer 140 can receive an IR light SF through the second metamaterial lens element 120. The second metamaterial lens element 120 can provide a second refractive index N2 for the IR light SF, so as to fine-tune the direction and phase of the IR light SF. For example, the IR light SF may be from any external object or any external device. According to practical measurements, the overall size of the optical device 100 using the first metamaterial lens element 110 and the second metamaterial lens element 120 can be significantly reduced due to the first metamaterial lens element 110 and the second metamaterial lens element 120's characteristics of thinness and lightness. Furthermore, the design flexibility of the optical device 100 can be further improved since the OLED layer 130 is well integrated with the IR sensor layer 140.

In some embodiments, the element sizes and element parameters of the optical device 100 will be described as follows. The operational frequency of the visible light ST may be from 400 THz to 790 THz. The operational frequency of the IR light SF may be from 300 GHz to 430 THz. For the visible light ST, the first refractive index N1 of the first metamaterial lens element 110 may be greater than 1. For the IR light SF, the second refractive index N2 of the second metamaterial lens element 120 may be smaller than 1. The above ranges of element sizes and element parameters are calculated and obtained according to many experimental results, and they help to minimize the overall size of the optical device 100, and also to optimize the equivalent refractive index of the optical device 100. However the invention is not limited thereto. In alternative embodiments, the first refractive index N1 of the first metamaterial lens element 110 is smaller than or equal to 1, and the second refractive index N2 of the second metamaterial lens element 120 is greater than or equal to 1.

The following embodiments will introduce different configurations and detail structural features of the optical device 100. It should be understood that these figures and descriptions are merely exemplary, rather than limitations of the invention.

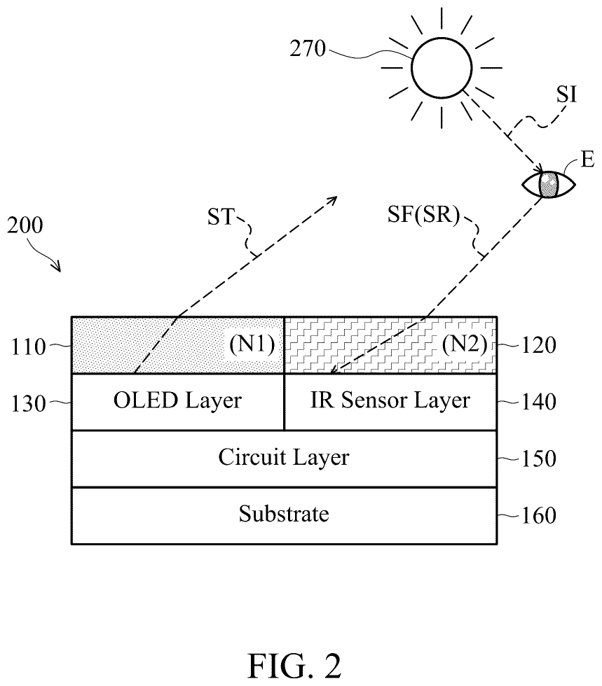

FIG. 2 is a sectional view of an optical device 200 according to an embodiment of the invention. FIG. 2 is similar to FIG. 1. In the embodiment of FIG. 2, the optical device 200 is an HMD (Head Mounted Display), and the optical device 200 further includes an IR light source 270. The IR light source 270 may be fixed on an outer frame of the HMD (not shown). The IR light source 270 can transmit an incident light SI to an eyeball E of a user. In response, the aforementioned IR light SF may be equivalent to a reflection light SR from the eyeball E of the user. For example, if the incident light SI has an LHCP (Left-Handed Circular Polarization), the reflection light SR may have an RHCP (Right-Handed Circular Polarization). Conversely, if the incident light SI has an RHCP, the reflection light SR may have an LHCP. The circuit layer 150 or a processor coupled thereto can obtain and analyze the relative information of the reflection light SR from the IR sensor layer 140, so as to estimate the movement or rotation of the eyeball E of the user. Thus, the optical device 200 can support an eye-tracking function. In addition, the second metamaterial lens element 120 can be configured to select the reflection light SR (i.e., the IR light SF) having a different polarization direction. In some embodiments, the second metamaterial lens element 120 can receive only the IR light SF with the LHCP, but the IR light SF with the RHCP can be filtered out by the second metamaterial lens element 120. However, the invention is not limited thereto. In alternative embodiments, the second metamaterial lens element 120 can receive only the IR light SF with the RHCP, but the IR light SF with the LHCP can be filtered out by the second metamaterial lens element 120. According to practical measurements, such a polarization-selecting design can eliminate a variety of light noise, and it can help to increase the detection accuracy of the IR sensor layer 140 and the circuit layer 150. Other features of the optical device 200 of FIG. 2 are similar to those of the optical device 100 of FIG. 1. Accordingly, the two embodiments can achieve similar levels of performance.

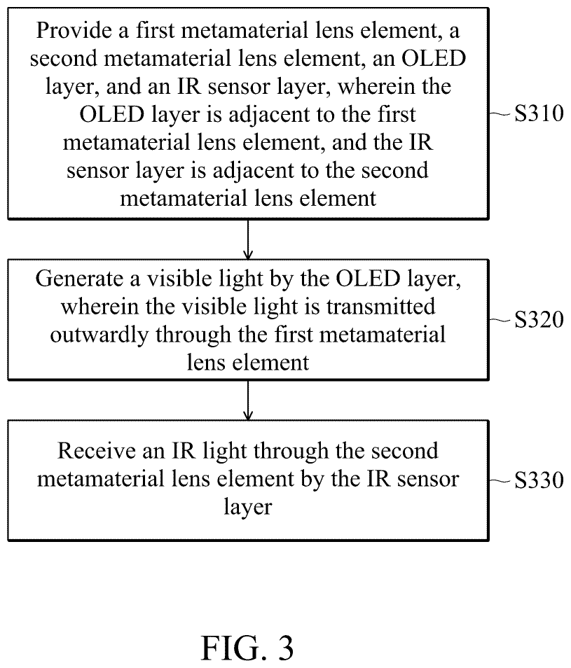

FIG. 3 is a flowchart of an optical method according to an embodiment of the invention. To begin, in step S310, a first metamaterial lens element, a second metamaterial lens element, an OLED layer, and an IR sensor layer are provided. The OLED layer is adjacent to the first metamaterial lens element. The IR sensor layer is adjacent to the second metamaterial lens element. In step S320, a visible light is generated by the OLED layer. The visible light is transmitted outwardly through the first metamaterial lens element. Finally, in step S330, an IR light is received through the second metamaterial lens element by the IR sensor layer. It should be understood that these steps are not required to be performed in order, and every feature of the embodiments of FIG. 1 and FIG. 2 may be applied to the optical method of FIG. 3.

The invention proposes a novel optical device and a novel optical method. In comparison to the conventional design, the invention has at least the advantages of reducing the overall size, increasing the equivalent refractive index, improving the integration, and enhancing the spatial diversity. Therefore, the invention is suitable for application in a variety of devices.

Note that the above element sizes and element parameters are not limitations of the invention. A designer can fine-tune these setting values according to different requirements. It should be understood that the optical device and the optical method of the invention are not limited to the configurations of FIGS. 1-3. The invention may include any one or more features of any one or more embodiments of FIGS. 1-3. In other words, not all of the features displayed in the figures should be implemented in the optical device and the optical method of the invention.

The method of the invention, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

It will be apparent to those skilled in the art that various modifications and variations can be made in the invention. It is intended that the standard and examples be considered as exemplary only, with a true scope of the disclosed embodiments being indicated by the following claims and their equivalents.

What is claimed is:

1. An optical device, comprising:
a first metamaterial lens element;
a second metamaterial lens element;
an OLED (Organic Light-Emitting Diode) layer, disposed adjacent to the first metamaterial lens element;
an IR (Infrared) sensor layer, disposed adjacent to the second metamaterial lens element;
a circuit layer, carrying the OLED layer and the IR sensor layer; and
a substrate, carrying the circuit layer;
wherein the OLED layer generates a visible light, and the visible light is transmitted outwardly through the first metamaterial lens element;
wherein the IR sensor layer receives an IR light through the second metamaterial lens element.

2. The optical device as claimed in claim 1, wherein the first metamaterial lens element and the second metamaterial lens element have different periodical structures.

3. The optical device as claimed in claim 1, wherein the first metamaterial lens element provides a first refractive index for the visible light.

4. The optical device as claimed in claim 3, wherein the first refractive index is greater than 1.

5. The optical device as claimed in claim 1, wherein the second metamaterial lens element provides a second refractive index for the IR light.

6. The optical device as claimed in claim 5, wherein the second refractive index is smaller than 1.

7. The optical device as claimed in claim 1, wherein the optical device is an HMD (Head Mounted Display).

8. The optical device as claimed in claim 1, further comprising:
an IR light source, transmitting an incident light to an eyeball, wherein the IR light is equivalent to a reflection light from the eyeball.

9. The optical device as claimed in claim 8, wherein if the incident light has an LHCP (Left-Handed Circular Polarization), the reflection light has an RHCP (Right-Handed Circular Polarization).

10. The optical device as claimed in claim 8, wherein if the incident light has an RHCP, the reflection light has an LHCP.

11. The optical device as claimed in claim 1, wherein the optical device supports an eye-tracking function.

12. The optical device as claimed in claim 1, wherein the second metamaterial lens element only receives either the IR light with an LHCP or the IR light with an RHCP.

13. An optical method, comprising the steps of:
providing a first metamaterial lens element, a second metamaterial lens element, an OLED layer, and an IR sensor layer, wherein the OLED layer is adjacent to the first metamaterial lens element, and the IR sensor layer is adjacent to the second metamaterial lens element;
generating a visible light by the OLED layer, wherein the visible light is transmitted outwardly through the first metamaterial lens element; and
receiving an IR light through the second metamaterial lens element by the IR sensor layer.

14. The optical method as claimed in claim 13, wherein the first metamaterial lens element and the second metamaterial lens element have different periodical structures.

15. The optical method as claimed in claim 13, further comprising:
providing a first refractive index for the visible light by the first metamaterial lens element.

16. The optical method as claimed in claim 13, further comprising:
providing a second refractive index for the IR light by the second metamaterial lens element.

17. The optical method as claimed in claim 13, further comprising:
transmitting an incident light to an eyeball by an IR light source, wherein the IR light is equivalent to a reflection light from the eyeball.

18. The optical method as claimed in claim 17, wherein if the incident light has an LHCP, the reflection light has an RHCP.

19. The optical method as claimed in claim 17, wherein if the incident light has an RHCP, the reflection light has an LHCP.

20. The optical method as claimed in claim 13, further comprising:
receiving either the IR light with an LHCP or the IR light with an RHCP by the second metamaterial lens element.
